(19) United States
(12) Patent Application Publication
(10) Pub. No.: US 2026/0058616 A1
(43) Pub. Date: Feb. 26, 2026

(54) RADIO FREQUENCY AMPLIFIER

(71) Applicant: Murata Manufacturing Co., Ltd., Nagaokakyo-shi (JP)

(72) Inventor: Yuri HONDA, Nagaokakyo-shi (JP)

(21) Appl. No.: 19/295,755

(22) Filed: Aug. 11, 2025

(30) Foreign Application Priority Data
Aug. 21, 2024 (JP) 2024-139691

(51) Int. Cl. H03F 3/195; H03F 1/56

(52) U.S. Cl. CPC H03F 3/195; H03F 1/565; H03F 2200/451

(57) ABSTRACT

A radio frequency amplifier includes at least one amplifier stage. The radio frequency amplifier includes a first amplifier including an output that is electrically connected to an output terminal of the radio frequency amplifier and an input that receives a radio frequency signal, and an inductor including a first end that is electrically connected to the output of the first amplifier and a second end that is electrically connected to the input of the first amplifier.

### CROSS REFERENCE TO RELATED APPLICATION

This application claims priority from Japanese Patent Application No. 2024-139691, filed on Aug. 21, 2024. The content of these applications are incorporated herein by reference in its entirety.

### BACKGROUND OF THE DISCLOSURE

### 1. Field of the Disclosure

The present disclosure relates to a radio frequency amplifier.

### 2. Description of the Related Art

Japanese Unexamined Patent Application Publication No. 2001-292039 describes a pre-distortion compensation circuit that is disposed in front of an amplifier and generates an intermodulation distortion component that can substantially cancel out an intermodulation distortion component generated by the amplifier.

### BRIEF SUMMARY OF THE DISCLOSURE

The pre-distortion compensation circuit described in Japanese Unexamined Patent Application Publication No. 2001-292039 includes a large number of circuit components and therefore has a large circuit size.

The present disclosure has been made in view of the above problem, and a possible benefit of the present disclosure is to suppress unnecessary signals while reducing the circuit size.

An aspect of the present disclosure provides a radio frequency amplifier including at least one amplifier stage. The radio frequency amplifier includes a first amplifier including an output that is electrically connected to an output terminal of the radio frequency amplifier and an input that receives a radio frequency signal, and an inductor including a first end that is electrically connected to the output of the first amplifier and a second end that is electrically connected to the input of the first amplifier.

A radio frequency amplifier according to the present disclosure makes it possible to suppress unnecessary signals while reducing the circuit size.

### BRIEF DESCRIPTION OF THE SEVERAL VIEWS OF THE DRAWINGS

FIG. 1 is a diagram illustrating a configuration of a radio frequency amplifier according to a comparative example;

FIG. 2 is a diagram illustrating a circuit configuration of a radio frequency amplifier according to a first embodiment;

FIG. 3 is a diagram illustrating a circuit simulation model for the radio frequency amplifiers according to the comparative example and the first embodiment;

FIG. 4 is a graph showing a circuit simulation result of the radio frequency amplifier according to the comparative example;

FIG. 5 is a graph showing a circuit simulation result of the radio frequency amplifier according to the first embodiment; and

FIG. 6 is a diagram illustrating a circuit configuration of a radio frequency amplifier according to a second embodiment.

### DETAILED DESCRIPTION OF THE DISCLOSURE

Embodiments of the present disclosure are described in detail below with reference to the drawings. However, the present disclosure is not limited to those embodiments. Needless to say, the embodiments are examples, and partial substitutions and combinations of components in different embodiments may be made. In the second and subsequent embodiments, descriptions of features that are the same as those in the first embodiment are omitted, and only differences are described. In particular, the description of the same effect provided by the same feature is not repeated for each embodiment.

### First Embodiment

To facilitate the understanding of a first embodiment, a comparative example is described before the first embodiment.

### Configuration of Comparative Example

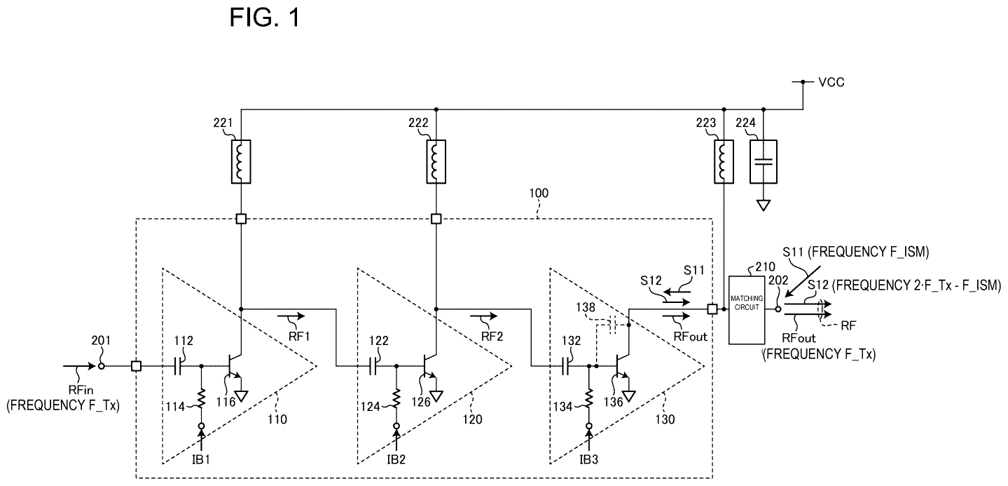

FIG. 1 is a diagram illustrating a configuration of a radio frequency amplifier according to the comparative example.

A radio frequency amplifier 100 amplifies a radio frequency input signal RFin and outputs an amplified radio frequency output signal RFout.

A frequency F_Tx indicates the frequency of the carrier wave of the radio frequency input signal RFin and the radio frequency output signal RFout.

The radio frequency amplifier 100 is a three-stage amplifier that includes an initial stage amplifier 110, an intermediate stage amplifier 120, and a final stage amplifier 130.

Although the number of stages of the radio frequency amplifier 100 is three in this example, the present disclosure is not limited to this example. The number of stages of the radio frequency amplifier 100 may be one, two, four, or more.

The amplifier 110 includes a capacitor 112, a resistor 114, and a transistor 116.

A first end of the capacitor 112 is electrically connected to a terminal 201. The radio frequency input signal RFin is inputted to the terminal 201. A second end of the capacitor 112 is electrically connected to the base of the transistor 116. The capacitor 112 is a DC blocking capacitor that blocks the direct-current component of the radio frequency input signal RFin.

A bias current IB1 is inputted to a first end of the resistor 114. A second end of the resistor 114 is electrically connected to the base of the transistor 116. The bias current IB1 is inputted to the base of the transistor 116 via the resistor 114.

The emitter of the transistor 116 is electrically connected to a reference potential. The reference potential is, for example, but not limited to, a ground potential. That is, the transistor 116 is a grounded-emitter transistor. A power supply voltage VCC is supplied to the collector of the transistor 116 via a choke coil 221. The power supply voltage VCC is stabilized by a capacitor 224.

The transistor 116 amplifies the radio frequency input signal RFin inputted to the base and outputs an amplified radio frequency signal RF1 from the collector.

The amplifier 120 includes a capacitor 122, a resistor 124, and a transistor 126.

A first end of the capacitor 122 is electrically connected to the collector of the transistor 116. A second end of the capacitor 122 is electrically connected to the base of the transistor 126. The capacitor 122 is a DC blocking capacitor that blocks the direct-current component of the radio frequency signal RF1.

A bias current IB2 is inputted to a first end of the resistor 124. A second end of the resistor 124 is electrically connected to the base of the transistor 126. The bias current IB2 is inputted to the base of the transistor 126 via the resistor 124.

The emitter of the transistor 126 is electrically connected to the reference potential. That is, the transistor 126 is a grounded-emitter transistor. The power supply voltage VCC is supplied to the collector of the transistor 126 via a choke coil 222.

The transistor 126 amplifies the radio frequency signal RF1 inputted to the base and outputs an amplified radio frequency signal RF2 from the collector.

The amplifier 130 includes a capacitor 132, a resistor 134, and a transistor 136.

A first end of the capacitor 132 is electrically connected to the collector of the transistor 126. A second end of the capacitor 132 is electrically connected to the base of the transistor 136. The capacitor 132 is a DC blocking capacitor that blocks the direct-current component of the radio frequency signal RF2.

A bias current IB3 is inputted to a first end of the resistor 134. A second end of the resistor 134 is electrically connected to the base of the transistor 136. The bias current IB3 is inputted to the base of the transistor 136 via the resistor 134.

The emitter of the transistor 136 is electrically connected to the reference potential. That is, the transistor 136 is a grounded-emitter transistor. The power supply voltage VCC is supplied to the collector of the transistor 136 via a choke coil 223.

The transistor 136 amplifies the radio frequency signal RF2 inputted to the base and outputs the amplified radio frequency output signal RFout from the collector.

The collector of the transistor 136 is electrically connected to a terminal 202 via a matching circuit 210.

The transistor 136 has a parasitic capacitance 138 between the base and the collector.

### Problem in Comparative Example

For example, the frequency F_Tx is 1910 MHz. Also, assume that a radio frequency signal S11 in the Industrial, Scientific and Medical (ISM) band is transmitted from a load (not shown) to the terminal 202. For example, a frequency F_ISM of the carrier wave of the radio frequency signal S11 is 2400 MHz.

The radio frequency signal S11 transmitted to the terminal 202 is transmitted to the collector of the transistor 136 via the matching circuit 210. The radio frequency signal S11 transmitted to the collector of the transistor 136 is transmitted to the base of the transistor 136 via the parasitic capacitance 138. Also, the radio frequency signal RF2 is inputted to the base of the transistor 136.

Accordingly, the radio frequency signal RF2 and the radio frequency signal S11 are mixed and amplified by the transistor 136.

In other words, an output signal RF of the radio frequency amplifier 100 includes a component corresponding to the radio frequency output signal RFout and a component corresponding to a radio frequency signal S12 that is obtained by mixing and amplifying the radio frequency signal RF2 and the radio frequency signal S11. The frequency of the radio frequency signal S12 is, for example, 2·F_Tx−F_ISM.

For example, when the frequency F_Tx is 1910 MHz and the frequency F_ISM is 2400 MHz, the frequency of the radio frequency signal S12 is 2.1910−2400=1420 MHz.

It is undesirable that the output signal RF of the radio frequency amplifier 100 includes the radio frequency signal S12 as a component. That is, it is desirable to suppress the component corresponding to the radio frequency signal S12 in the output signal RF of the radio frequency amplifier 100.

### Configuration of First Embodiment

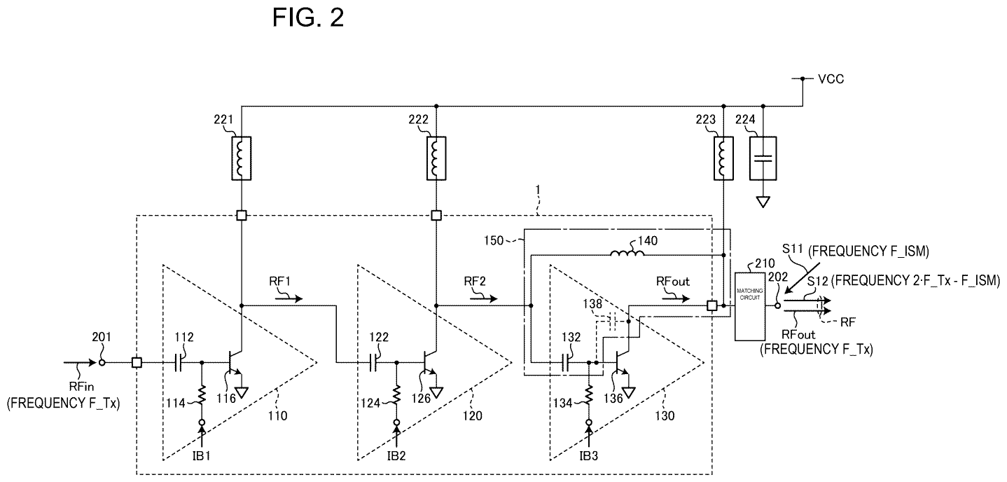

FIG. 2 is a diagram illustrating a configuration of a radio frequency amplifier according to the first embodiment.

Compared with the radio frequency amplifier 100 of the comparative example, a radio frequency amplifier 1 further includes an inductor 140.

A first end of the inductor 140 is electrically connected to an output of the amplifier 130 (the collector of the transistor 136). A second end of the inductor 140 is electrically connected to the output of the amplifier 120 (the collector of the transistor 126) and the input of the amplifier 130 (a first end of the capacitor 132).

The amplifier 130 corresponds to an example of “first amplifier” of the present disclosure. The capacitor 132 corresponds to an example of “first capacitor” of the present disclosure. The transistor 136 corresponds to an example of “transistor” of the present disclosure. The inductor 140 corresponds to an example of “inductor” of the present disclosure.

The capacitor 132 and the parasitic capacitance 138, which are connected in series, and the inductor 140 constitute an LC parallel resonant circuit 150.

The LC parallel resonant circuit 150 corresponds to an example of “first parallel resonant circuit” of the present disclosure.

For example, the inductance value of the inductor 140 is set such that the resonant frequency of the LC parallel resonant circuit 150 matches the frequency F_ISM. However, the present disclosure is not limited to this example.

With this configuration, the radio frequency amplifier 1 can increase the impedance at the frequency F_ISM that is observed when the base of the transistor 136 is seen from the collector of the transistor 136.

Accordingly, the radio frequency amplifier 1 can reduce the amplitude of the radio frequency signal S11 (frequency F_ISM) at the base end of the transistor 136 and can thereby reduce the component corresponding to the radio frequency signal S12 (frequency 2·F_Tx−F_ISM) in the output signal.

The radio frequency amplifier 1 can be implemented by adding one inductor 140. Therefore, compared with the pre-distortion compensation circuit described in Japanese Unexamined Patent Application Publication No. 2001-292039, this configuration makes it possible to reduce the number of circuit components and thereby reduce the circuit size.

### Circuit Simulation

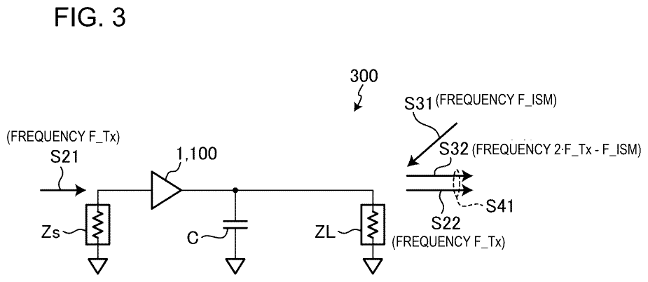

FIG. 3 is a diagram illustrating a circuit simulation model for the comparative example and the first embodiment.

A circuit simulation model 300 includes the radio frequency amplifier 1 or the radio frequency amplifier 100, an impedance circuit Zs, a capacitor C, and an impedance circuit ZL.

A first end of the impedance circuit Zs is electrically connected to the input terminal of the radio frequency amplifier 1 or the radio frequency amplifier 100. A second end of the impedance circuit Zs is electrically connected to a reference potential.

A first end of the capacitor C is electrically connected to the output terminal of the radio frequency amplifier 1 or the radio frequency amplifier 100. A second end of the capacitor C is electrically connected to the reference potential.

A first end of the impedance circuit ZL is electrically connected to the output terminal of the radio frequency amplifier 1 or the radio frequency amplifier 100. A second end of the impedance circuit ZL is electrically connected to the reference potential.

In this circuit simulation model 300, a radio frequency signal S21 (frequency F_Tx) is inputted to the input terminal of the radio frequency amplifier 1 or the radio frequency amplifier 100, and a radio frequency signal S31 (frequency F_ISM) is inputted to the output terminal of the radio frequency amplifier 1 or the radio frequency amplifier 100. Also, the phase of the radio frequency signal S31 is shifted from the phase of the radio frequency signal S21.

A radio frequency output signal S41 of the radio frequency amplifier 1 or the radio frequency amplifier 100 includes a component corresponding to a radio frequency signal S22 (frequency F_Tx) obtained by amplifying the radio frequency signal S21 and a component corresponding to a radio frequency signal S32 (frequency 2·F_Tx−F_ISM) obtained by mixing and amplifying the radio frequency signals S21 and S31.

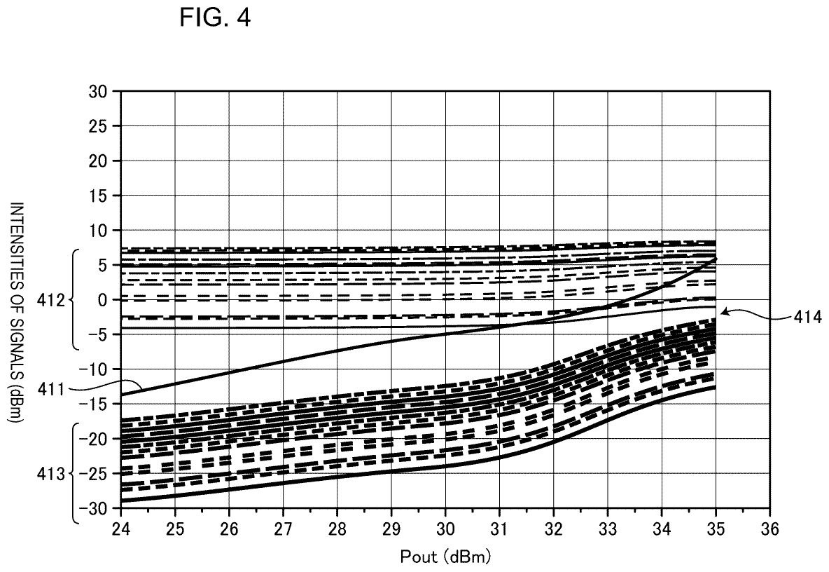

FIG. 4 is a graph showing a circuit simulation result of the radio frequency amplifier according to the comparative example.

In FIG. 4, the horizontal axis represents an intensity Pout (dBm) of the radio frequency signal S22 (frequency F_Tx), and the vertical axis represents intensities (dBm) of respective signals.

A line 411 indicates the intensity of a second harmonic wave (frequency 2·F_Tx) of the radio frequency signal S21 generated by the radio frequency amplifier 100.

A line group 412 indicates the intensities of the radio frequency signal S31 (frequency F_ISM) amplified by the radio frequency amplifier 100. Lines in the line group 412 indicate the intensities of the amplified radio frequency signal S31 observed when the phase of the radio frequency signal S31 is varied.

A line group 413 indicates the intensities of the radio frequency signal S32 (frequency 2·F_Tx−F_ISM) outputted from the radio frequency amplifier 100. Lines in the line group 412 indicate the intensities of the radio frequency signal S32 observed when the phase of the radio frequency signal S31 is varied.

As indicated by a point 414, the intensity of the radio frequency signal S32 (frequency 2·F_Tx−F_ISM) peaks when the intensity of the radio frequency signal S22 (frequency F_Tx) is approximately 35 dBm. The intensity of the radio frequency signal S32 (frequency 2·F_Tx−F_ISM) at the point 414 is approximately-3 dBm.

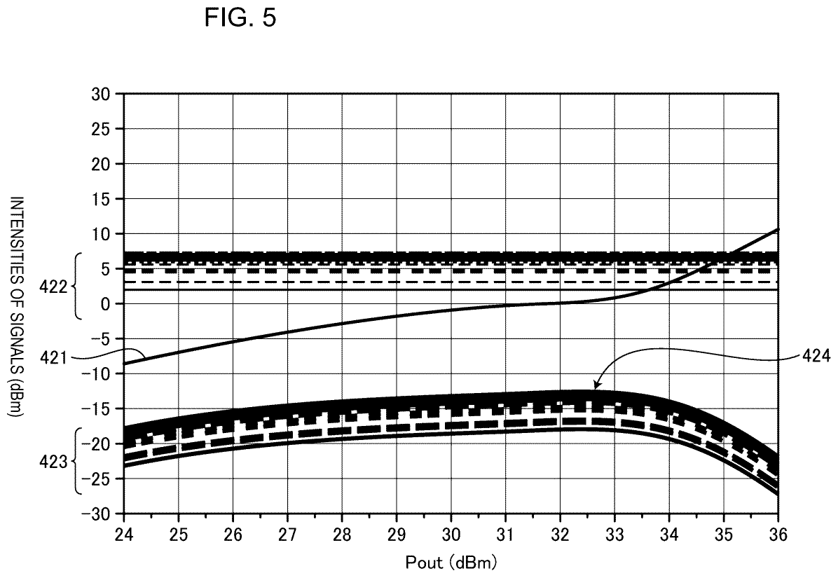

FIG. 5 is a graph showing a circuit simulation result of the radio frequency amplifier according to the first embodiment.

In FIG. 5, the horizontal axis represents an intensity Pout (dBm) of the radio frequency signal S22 (frequency F_Tx), and the vertical axis represents the intensities (dBm) of respective signals.

A line 421 indicates the intensity of a second harmonic wave (frequency 2·F_Tx) of the radio frequency signal S21 generated by the radio frequency amplifier 1.

A line group 422 indicates the intensities of the radio frequency signal S31 (frequency F_ISM) amplified by the radio frequency amplifier 1. Lines in the line group 422 indicate the intensities of the amplified radio frequency signal S31 observed when the phase of the radio frequency signal S31 is varied.

A line group 423 indicates the intensities of the radio frequency signal S32 (frequency 2·F_Tx−F_ISM) outputted from the radio frequency amplifier 1. Lines in the line group 423 indicate the intensities of the radio frequency signal S32 observed when the phase of the radio frequency signal S31 is varied.

As indicated by a point 424, the intensity of the radio frequency signal S32 (frequency 2·F_Tx−F_ISM) peaks when the intensity of the radio frequency signal S22 (frequency F_Tx) is approximately 32 dBm. The intensity of the radio frequency signal S32 (frequency 2·F_Tx−F_ISM) at the point 424 is approximately −13 dBm.

The radio frequency amplifier 1 can make the maximum intensity (approximately −13 dBm, see the point 424) of the radio frequency signal S32 smaller than the maximum intensity (approximately −3 dBm, see the point 414) of the radio frequency signal S32 observed using the radio frequency amplifier 100.

### Effects

The radio frequency amplifier 1 can increase the impedance at the frequency F_ISM that is observed when the base of the transistor 136 is seen from the collector of the transistor 136. Therefore, the radio frequency amplifier 1 can reduce the amplitude of the radio frequency signal S11 (frequency F_ISM) at the base end of the transistor 136 and thereby reduce the component corresponding to the radio frequency signal S12 (frequency 2·F_Tx−F_ISM) in the output signal RF.

Referring to FIGS. 4 and 5, the radio frequency amplifier 1 can make the maximum intensity (approximately −13 dBm, see the point 424) of the radio frequency signal S32 smaller than the maximum intensity (approximately −3 dBm, see the point 414) of the radio frequency signal S32 observed using the radio frequency amplifier 100.

Also, the radio frequency amplifier 1 can be implemented by adding one inductor 140. Therefore, compared with the pre-distortion compensation circuit described in Japanese Unexamined Patent Application Publication No. 2001-292039, the configuration of the radio frequency amplifier 1 makes it possible to reduce the number of circuit components and thereby reduce the circuit size.

### Second Embodiment

### Configuration

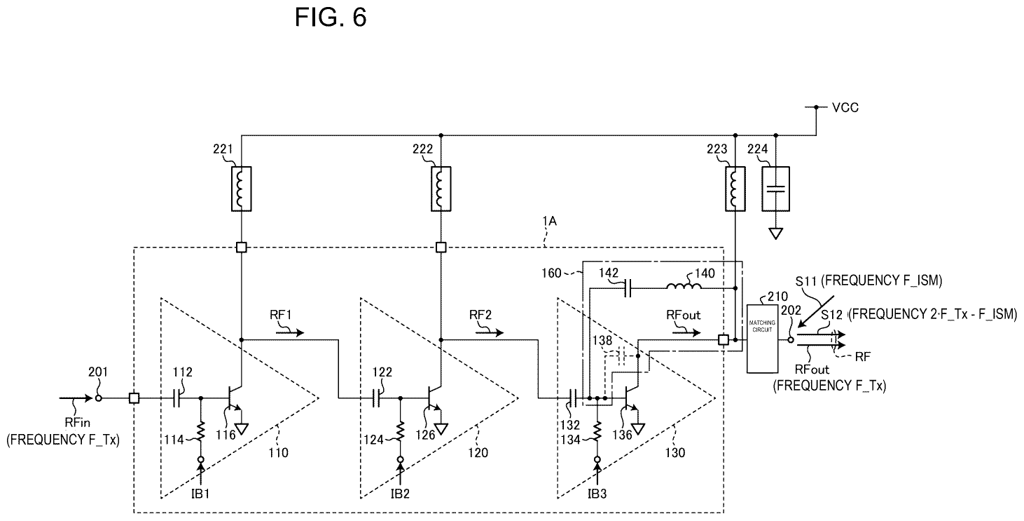

FIG. 6 is a diagram illustrating a configuration of a radio frequency amplifier according to a second embodiment.

Compared with the radio frequency amplifier 1 of the first embodiment (see FIG. 2), a radio frequency amplifier 1A further includes a capacitor 142.

The capacitor 142 corresponds to an example of “second capacitor” of the present disclosure.

A first end of the capacitor 142 is electrically connected to the second end of the inductor 140. A second end of the capacitor 142 is electrically connected to the base of the transistor 136.

The capacitor 142 is a DC blocking capacitor that blocks an electric current flowing to the inductor 140 as a result of the collector-base voltage of the transistor 136.

The inductor 140 and the capacitor 142, which are connected in series, and the parasitic capacitance 138 constitute an LC parallel resonant circuit 160.

The LC parallel resonant circuit 160 corresponds to an example of “second parallel resonant circuit” of the present disclosure.

For example, the inductance value of the inductor 140 and the electrostatic capacitance value of the capacitor 142 are set such that the resonant frequency of the LC parallel resonant circuit 160 matches the frequency F_ISM. However, the present disclosure is not limited to this example.

### Effects

The radio frequency amplifier 1A can increase the impedance at the frequency F_ISM that is observed when the base of the transistor 136 is seen from the collector of the transistor 136. Therefore, the radio frequency amplifier 1A can reduce the amplitude of the radio frequency signal S11 (frequency F_ISM) at the base end of the transistor 136 and thereby reduce the component corresponding to the radio frequency signal S12 (frequency 2·F_Tx−F_ISM) in the output signal RF.

Also, the radio frequency amplifier 1A can be implemented by adding one inductor 140 and one capacitor 142. Therefore, compared with the pre-distortion compensation circuit described in Japanese Unexamined Patent Application Publication No. 2001-292039, the configuration of the radio frequency amplifier 1A makes it possible to reduce the number of circuit components and thereby reduce the circuit size.

### Examples of Configurations of Present Disclosure

The present disclosure may be implemented by configurations as described below.

(1) A radio frequency amplifier includes at least one amplifier stage. The radio frequency amplifier includes a first amplifier including an output that is electrically connected to an output terminal of the radio frequency amplifier and an input that receives a radio frequency signal, and an inductor including a first end that is electrically connected to the output of the first amplifier and a second end that is electrically connected to the input of the first amplifier.

(2) In the radio frequency amplifier described in (1), the first amplifier includes a first capacitor including a first end to which the radio frequency signal is input, and a transistor including an emitter that is grounded, a base that is electrically connected to a second end of the first capacitor, and a collector that outputs an amplified radio frequency signal; the first end of the inductor is electrically connected to the collector of the transistor; and the second end of the inductor is electrically connected to the first end of the first capacitor.

(3) In the radio frequency amplifier described in (2), the transistor has a parasitic capacitance between the base and the collector; and the parasitic capacitance and the first capacitor, which are connected in series, and the inductor constitute a first parallel resonant circuit.

(4) In the radio frequency amplifier described in (3), an inductance value of the inductor is set such that the resonant frequency of the first parallel resonant circuit matches the frequency of a signal transmitted to an output terminal of the first amplifier.

(5) The radio frequency amplifier described in (1) further includes a second capacitor. The first amplifier includes a transistor including an emitter that is grounded, a base that receives the radio frequency signal, and a collector that outputs an amplified radio frequency signal; the first end of the inductor is electrically connected to the collector of the transistor; the second end of the inductor is electrically connected to a first end of the second capacitor; and a second end of the second capacitor is electrically connected to the base of the transistor.

(6) In the radio frequency amplifier described in (5), the transistor has a parasitic capacitance between the base and the collector; and the inductor and the second capacitor, which are connected in series, and the parasitic capacitance constitute a second parallel resonant circuit.

(7) In the radio frequency amplifier described in (6), the inductance value of the inductor and the electrostatic capacitance value of the second capacitor are set such that a resonant frequency of the second parallel resonant circuit matches the frequency of a signal transmitted to an output terminal of the first amplifier.

The above-described embodiments are intended to facilitate the understanding of the present disclosure and are not intended to limit the scope of the present disclosure. The present disclosure may be modified or improved without departing from the spirit of the present disclosure, and the present disclosure may include its equivalents.

What is claimed is:

1. A radio frequency amplifier including at least one amplifier stage, the radio frequency amplifier comprising:
a first amplifier including an output that is electrically connected to an output terminal of the radio frequency amplifier and an input that receives a radio frequency signal; and
an inductor including a first end that is electrically connected to the output of the first amplifier and a second end that is electrically connected to the input of the first amplifier.

2. The radio frequency amplifier according to claim 1, wherein
the first amplifier includes
a first capacitor including a first end to which the radio frequency signal is inputted, and
a transistor including an emitter that is electrically connected to a reference potential, a base that is electrically connected to a second end of the first capacitor, and a collector that outputs an amplified radio frequency signal;
the first end of the inductor is electrically connected to the collector of the transistor; and
the second end of the inductor is electrically connected to the first end of the first capacitor.

3. The radio frequency amplifier according to claim 2, wherein the reference potential is ground.

4. The radio frequency amplifier according to claim 2, wherein
the transistor has a parasitic capacitance between the base and the collector; and
the parasitic capacitance and the first capacitor, which are connected in series, and the inductor constitute a first parallel resonant circuit.

5. The radio frequency amplifier according to claim 4, wherein
an inductance value of the inductor is set such that a resonant frequency of the first parallel resonant circuit matches a frequency of a signal transmitted to an output of the first amplifier.

6. The radio frequency amplifier according to claim 1, further comprising:
a second capacitor, wherein
the first amplifier includes a transistor including an emitter that is electrically connected to a reference potential, a base that receives the radio frequency signal, and a collector that outputs an amplified radio frequency signal;
the first end of the inductor is electrically connected to the collector of the transistor;
the second end of the inductor is electrically connected to a first end of the second capacitor; and
a second end of the second capacitor is electrically connected to the base of the transistor.

7. The radio frequency amplifier according to claim 6, wherein the reference potential is ground.

8. The radio frequency amplifier according to claim 6, wherein
the transistor has a parasitic capacitance between the base and the collector; and
the inductor and the second capacitor, which are connected in series, and the parasitic capacitance constitute a second parallel resonant circuit.

9. The radio frequency amplifier according to claim 7, wherein
an inductance value of the inductor and an electrostatic capacitance value of the second capacitor are set such that a resonant frequency of the second parallel resonant circuit matches a frequency of a signal transmitted to an output of the first amplifier.
